(19) United States
(12) Patent Application Publication
(10) Pub. No.: US 2024/0063771 A1
(43) Pub. Date: Feb. 22, 2024

(54) HIGH PASS POWER SPLITTER/COMBINER WITH REDUCED CIRCUIT AREA

(71) Applicant: Apple Inc., Cupertino, CA (US)

(72) Inventors: Milad Darvishi, San Diego, CA (US); Zhengan Yang, San Diego, CA (US)

(21) Appl. No.: 17/890,758

(22) Filed: Aug. 18, 2022

(51) Int. Cl. H03H 7/48; H04B 1/16

(52) U.S. Cl. CPC H03H 7/485; H04B 1/16

(57) ABSTRACT

An electronic device includes multiple antennas to transmit one or more signals, and a transceiver electrically coupled to the antennas. A transmitter of the transceiver may include splitter circuitry with reduced circuit area that may receive an input signal and generates multiple signals. Moreover, a receiver of the transceiver may include combiner circuitry with reduced circuit area that may receive multiple input signal and generates one output signal. The splitter and/or combiner may include combined circuitry including one or more inductors and resistors to provide a desired total impedance. Moreover, in different embodiments, the splitter and/or combiner may have different number of input or output ports.

### BACKGROUND

The present disclosure relates generally to wireless communication, and more specifically to filtering out-of-band frequencies from an input signal.

In an electronic device, a transceiver may include one or more amplifiers coupled to splitter/combiner circuitry to facilitate beam-forming. The splitter/combiner circuitry may be used as a low-pass filter and/or high-pass filter to reject undesired frequencies in an input signal. As silicon devices continue to shrink in size, some components of the electronic device may not scale with the rest of the shrinking components. In particular, the splitter/combiner circuitry may include one or more components that have non-scalable silicon footprints when placed on a circuitry board, such as one or more inductors disposed in the splitter/combiner circuitry.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, splitter circuitry includes a first inductor, a first capacitor, and a second capacitor coupled at an input node. The splitter circuitry may also include a first resistor coupled to the first capacitor at a first output node, a second inductor coupled to the first resistor and the first capacitor at the first output node. Moreover, the splitter circuitry may include a second resistor coupled to the second capacitor at a second output node, and a third inductor coupled to the second resistor and the second capacitor at the second output node and coupled to the second inductor at a coupling node.

In another embodiment, an electronic device includes multiple antennas that may transmit one or more signals. The electronic device may also include splitter circuitry coupled to the antennas. The splitter circuitry may include a first inductor, a first capacitor, and a second capacitor coupled at an input node. The splitter circuitry may also include a first resistor coupled to the first capacitor at a first output node, and a second inductor coupled to the first resistor and the first capacitor at the first output node. A first one or more antennas of multiple antennas may be coupled to the first resistor and the first capacitor at the first output node. Moreover, the splitter circuitry may include a second resistor coupled to the second capacitor at a second output node, and a third inductor coupled to the second resistor and the second capacitor at the second output node. A second one or more antennas may be coupled to the second resistor and the second capacitor at the second output node.

In yet another embodiment, a radio frequency (RF) receiver is described. The RF receiver may include a low noise amplifier and combiner circuitry coupled to the low noise amplifier. The combiner circuitry may include a first inductor, a first capacitor, and a second capacitor coupled at an output node. The combiner circuitry may also include a first resistor coupled to the first capacitor at a first input node, and a second inductor coupled to the first capacitor and the first resistor at the first input node. The low noise amplifier may be coupled to the first resistor and the first capacitor at the first input node. Moreover, the combiner circuitry may include a second resistor coupled to the second capacitor at a second input node, and a third inductor coupled to the second capacitor and the second resistor at the second input node. The low noise amplifier may be coupled to the second resistor and the second capacitor at the second input node.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts.

FIG. 1 is a block diagram of an electronic device, according to embodiments of the present disclosure;

FIG. 2 is a functional diagram of the electronic device of FIG. 1, according to embodiments of the present disclosure;

FIG. 3 is a schematic diagram of a transmitter of the electronic device of FIG. 1, according to embodiments of the present disclosure;

FIG. 4 is a schematic diagram of a receiver of the electronic device of FIG. 1, according to embodiments of the present disclosure;

FIG. 5 is a circuit diagram of a two-to-one splitter/combiner circuitry with parallel inductor and resistors disposed in a transceiver of the electronic device of FIG. 1, according to embodiments of the present disclosure;

FIG. 6 is a layout illustrating two inductors of the two-to-one splitter/combiner circuitry with parallel inductor and resistors of FIG. 5, according to embodiments of the present disclosure;

FIG. 7 is a circuit diagram of a two-to-one splitter/combiner circuitry with series inductor and resistors disposed in the transceiver of the electronic device of FIG. 1, according to embodiments of the present disclosure;

FIG. 8 is a first layout illustrating two inductors of the two-to-one splitter/combiner circuitry with series inductor and resistors of FIG. 5 where the series inductor is square shaped, according to embodiments of the present disclosure;

FIG. 9 is a second layout illustrating two inductors of the two-to-one splitter/combiner circuitry with series inductor and resistors of FIG. 5 where the series inductor is rectangular, according to embodiments of the present disclosure;

FIG. 10 is a circuit diagram of a four-to-one splitter/combiner circuitry with parallel inductor and resistors disposed in the transceiver of the electronic device of FIG. 1, according to embodiments of the present disclosure;

FIG. 11 is a circuit diagram of a four-to-one splitter/combiner circuitry with series inductor and resistors disposed in the transceiver of the electronic device of FIG. 1, according to embodiments of the present disclosure;

FIG. 12 is a layout illustrating five inductors of the four-to-one splitter/combiner circuitry with series inductor and resistors of FIG. 11 where the series inductor is square shaped, according to embodiments of the present disclosure; and

FIG. 13 is a circuit diagram of a three-to-one splitter/combiner circuitry with series inductor and resistors disposed in the transceiver of the electronic device of FIG. 1, according to embodiments of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on.

This disclosure is directed to reducing circuit area of (e.g., silicon footprint of) splitter/combiner circuitry in a transceiver and improving the efficiency of the splitter/combiner circuitry. Components in communication circuitry (e.g., the transceiver, a transmitter, a receiver) are shrinking and, as such, smaller surface area is desired for the communication circuitry in an electronic device. However, particular non-scalable components used in the communication circuitry may not scale with silicon components coupled to the non-scalable components. This may limit the minimum amount of surface area to implement the communication circuitry and the components of the communication circuitry. A common configuration of the splitter/combiner circuitry may include inductors, capacitors, and resistors to facilitate splitting an input signal and/or combining multiple input signals in a desired frequency range. In particular, inductors of the splitter/combiner circuitry may be non-scalable components that may not be shrinking or decreasing in size at the same rate as the other components in the splitter/configuration circuitry.

In some cases, the splitter/combiner circuitry may include one or more inductors and resistors coupled in parallel to facilitate filtering undesired frequencies and maintaining low energy loss. Embodiments herein provide various apparatuses to reduce the surface area of the splitter/combiner circuitry by combining such inductors and resistors of the splitter/combiner circuitry. For example, by coupling an inductor and a resistor of the splitter/combiner circuitry in series as compared to in parallel, an inductance value of the inductor may be reduced while maintaining a total impedance of the inductor and the resistor. Moreover, an area of an inductor may scale proportionally with an inductance of the inductor. Accordingly, a size of the inductor may be reduced such that the splitter/combiner circuitry may occupy a smaller surface area while filtering undesired frequencies and maintaining low energy loss.

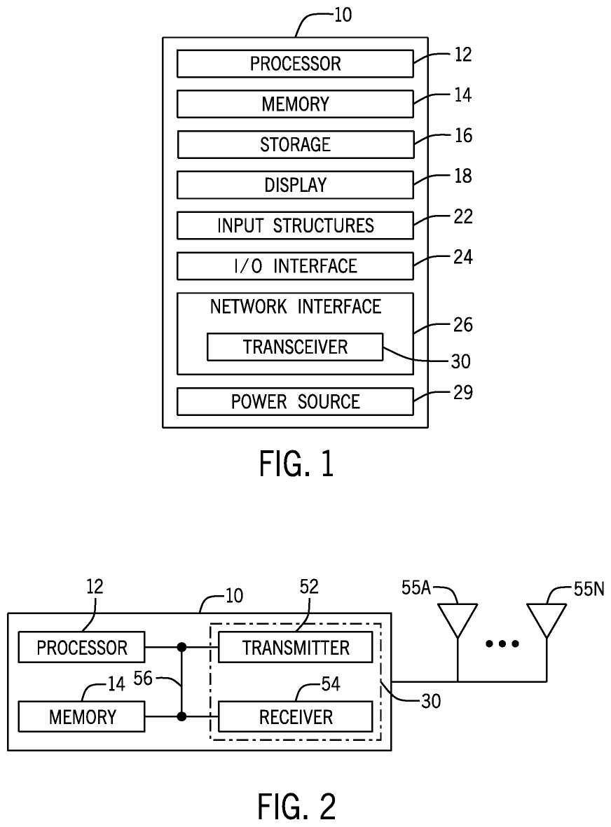

With this in mind, FIG. 1 is a block diagram of an electronic device 10, according to embodiments of the present disclosure. The electronic device 10 may include, among other things, one or more processors 12 (collectively referred to herein as a single processor for convenience, which may be implemented in any suitable form of processing circuitry), memory 14, nonvolatile storage 16, a display 18, input structures 22, an input/output (I/O) interface 24, a network interface 26, and a power source 29. The various functional blocks shown in FIG. 1 may include hardware elements (including circuitry), software elements (including machine-executable instructions) or a combination of both hardware and software elements (which may be referred to as logic). The processor 12, memory 14, the nonvolatile storage 16, the display 18, the input structures 22, the input/output (I/O) interface 24, the network interface 26, and/or the power source 29 may each be communicatively coupled directly or indirectly (e.g., through or via another component, a communication bus, a network) to one another to transmit and/or receive data between one another. It should be noted that FIG. 1 is merely one example of a particular implementation and is intended to illustrate the types of components that may be present in the electronic device 10.

By way of example, the electronic device 10 may include any suitable computing device, including a desktop or notebook computer (e.g., in the form of a MacBook®, MacBook® Pro, MacBook Air®, iMac®, Mac® mini, or Mac Pro® available from Apple Inc. of Cupertino, California), a portable electronic or handheld electronic device such as a wireless electronic device or smartphone (e.g., in the form of a model of an iPhone® available from Apple Inc. of Cupertino, California), a tablet (e.g., in the form of a model of an iPad® available from Apple Inc. of Cupertino, California), a wearable electronic device (e.g., in the form of an Apple Watch® by Apple Inc. of Cupertino, California), and other similar devices. It should be noted that the processor 12 and other related items in FIG. 1 may be embodied wholly or in part as software, hardware, or both. Furthermore, the processor 12 and other related items in FIG. 1 may be a single contained processing module or may be incorporated wholly or partially within any of the other elements within the electronic device 10. The processor 12 may be implemented with any combination of general-purpose microprocessors, microcontrollers, digital signal processors (DSPs), field programmable gate array (FPGAs), programmable logic devices (PLDs), controllers, state machines, gated logic, discrete hardware components, dedicated hardware finite state machines, or any other suitable entities that may perform calculations or other manipulations of information. The processors 12 may include one or more application processors, one or more baseband processors, or both, and perform the various functions described herein.

In the electronic device 10 of FIG. 1, the processor 12 may be operably coupled with the memory 14 and the nonvolatile storage 16 to perform various algorithms. Programs or instructions executed by the processor 12 may be stored in any suitable article of manufacture that includes one or more tangible, computer-readable media. The tangible, computer-readable media may include the memory 14 and/or the nonvolatile storage 16, individually or collectively, to store the instructions or routines. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor 12 to enable the electronic device 10 to provide various functionalities.

In certain embodiments, the display 18 may facilitate users to view images generated on the electronic device 10. In some embodiments, the display 18 may include a touch screen, which may facilitate user interaction with a user interface of the electronic device 10. Furthermore, it should be appreciated that, in some embodiments, the display 18 may include one or more liquid crystal displays (LCDs), light-emitting diode (LED) displays, organic light-emitting diode (OLED) displays, active-matrix organic light-emitting diode (AMOLED) displays, or some combination of these and/or other display technologies.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. In some embodiments, the I/O interface 24 may include an I/O port for a hardwired connection for charging and/or content manipulation using a standard connector and protocol, such as the Lightning connector provided by Apple Inc. of Cupertino, California, a universal serial bus (USB), or other similar connector and protocol. The network interface 26 may include, for example, one or more interfaces for a personal area network (PAN), such as an ultra-wideband (UWB) or a BLUETOOTH® network, a local area network (LAN) or wireless local area network (WLAN), such as a network employing one of the IEEE 802.11x family of protocols (e.g., WI-FI®), and/or a wide area network (WAN), such as any standards related to the Third Generation Partnership Project (3GPP), including, for example, a 3^{rd} generation (3G) cellular network, universal mobile telecommunication system (UMTS), 4^{th} generation (4G) cellular network, long term evolution (LTE®) cellular network, long term evolution license assisted access (LTE-LAA) cellular network, 5^{th} generation (5G) cellular network, and/or New Radio (NR) cellular network, a 6^{th} generation (6G) or greater than 6G cellular network, a satellite network, a non-terrestrial network, and so on. In particular, the network interface 26 may include, for example, one or more interfaces for using a cellular communication standard of the 5G specifications that include the millimeter wave (mmWave) frequency range (e.g., 24.25-300 giga-hertz (GHz)) that defines and/or enables frequency ranges used for wireless communication. The network interface 26 of the electronic device 10 may allow communication over the aforementioned networks (e.g., 5G, Wi-Fi, LTE-LAA, and so forth).

The network interface 26 may also include one or more interfaces for, for example, broadband fixed wireless access networks (e.g., WIMAX®), mobile broadband Wireless networks (mobile WIMAX®), asynchronous digital subscriber lines (e.g., ADSL, VDSL), digital video broadcasting-terrestrial (DVB-T®) network and its extension DVB Handheld (DVB-H®) network, ultra-wideband (UWB) network, alternating current (AC) power lines, and so forth.

As illustrated, the network interface 26 may include a transceiver 30. In some embodiments, all or portions of the transceiver 30 may be disposed within the processor 12. The transceiver 30 may support transmission and receipt of various wireless signals via one or more antennas, and thus may include a transmitter and a receiver. The power source 29 of the electronic device 10 may include any suitable source of power, such as a rechargeable lithium polymer (Li-poly) battery and/or an alternating current (AC) power converter.

FIG. 2 is a functional diagram of the electronic device 10 of FIG. 1, according to embodiments of the present disclosure. As illustrated, the processor 12, the memory 14, the transceiver 30, a transmitter 52, a receiver 54, and/or antennas 55 (illustrated as 55A-55N, collectively referred to as an antenna 55) may be communicatively coupled directly or indirectly (e.g., through or via another component, a communication bus, a network) to one another to transmit and/or receive data between one another.

The electronic device 10 may include the transmitter 52 and/or the receiver 54 that respectively enable transmission and reception of data between the electronic device 10 and an external device via, for example, a network (e.g., including base stations or access points) or a direct connection. As illustrated, the transmitter 52 and the receiver 54 may be combined into the transceiver 30. Moreover, the transmitter, the receiver, or both may include various circuitry including a splitter and/or a combiner with reduced circuit area, as will be appreciated.

The electronic device 10 may also have the antenna 55 electrically coupled to the transceiver 30. The antenna 55 may be configured in an omnidirectional or directional configuration, in a single-beam, dual-beam, or multi-beam arrangement, and so on. Each antenna of the antennas 55A-55N may be associated with one or more beams and various configurations. In some embodiments, multiple antennas of the antennas 55A-55N of an antenna group or module may be communicatively coupled a respective transceiver 30 and each emit radio frequency signals that may constructively and/or destructively combine to form a beam. The electronic device 10 may include multiple transmitters, multiple receivers, multiple transceivers, and/or multiple antennas as suitable for various communication standards. In some embodiments, the transmitter 52 and the receiver 54 may transmit and receive information via other wired or wireline systems or means.

As illustrated, the various components of the electronic device 10 may be coupled together by a bus system 56. The bus system 56 may include a data bus, for example, as well as a power bus, a control signal bus, and a status signal bus, in addition to the data bus. The components of the electronic device 10 may be coupled together or accept or provide inputs to each other using some other mechanism.

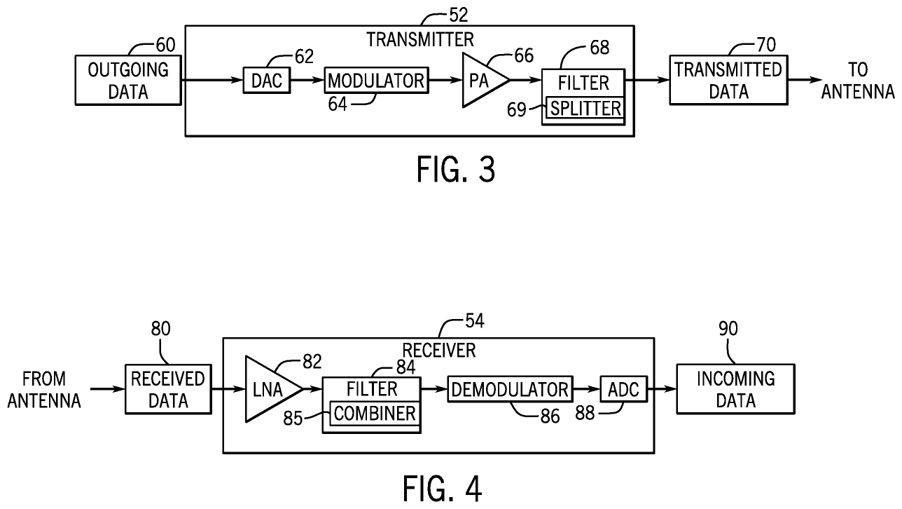

FIG. 3 is a schematic diagram of the transmitter 52 (e.g., transmit circuitry), according to embodiments of the present disclosure. As illustrated, the transmitter 52 may receive outgoing data 60 in the form of a digital signal to be transmitted via the antenna 55. A digital-to-analog converter (DAC) 62 of the transmitter 52 may convert the digital signal to an analog signal. Moreover, a modulator 64 may combine the analog signal with a carrier signal to generate a radio wave. A power amplifier (PA) 66 receives the modulated analog signal from the modulator 64. The power amplifier 66 may amplify the modulated analog signal to a suitable level to drive transmission of the signal via the antenna 55.

A filter 68 (e.g., filter circuitry and/or software) of the transmitter 52 may then remove undesirable noise from the amplified analog signal to generate transmitted data 70 to be transmitted via the antenna 55. The filter 68 may include a splitter 69 to split the amplified analog signal and/or remove undesirable noise from the amplified analog signal. In particular, the splitter 69 may split the amplified analog signal based on one or more frequency thresholds to provide two or more split analog signals. For example, the splitter 69 may facilitate beam-forming by providing the split analog signals via the antenna 55. Moreover, the splitter 69 may include any suitable filter or filters to remove the undesirable noise from the amplified analog signal, such as a bandpass filter, a bandstop filter, a low pass filter, a high pass filter, and/or a decimation filter.

Additionally, the transmitter 52 may include any suitable additional components not shown, or may not include certain of the illustrated components, such that the transmitter 52 may transmit the outgoing data 60 via the antenna 55. For example, the transmitter 52 may include a mixer and/or a digital up converter. As another example, the transmitter 52 may not include the modulator 64 in cases where the DAC 62 outputs the radio wave (e.g., the DAC 62 combines the analog signal with the carrier signal).

FIG. 4 is a schematic diagram of the receiver 54 (e.g., receive circuitry), according to embodiments of the present disclosure. As illustrated, the receiver 54 may receive received data 80 from the antenna 55 in the form of a number of analog signals. A low noise amplifier (LNA) 82 may amplify the received analog signals to a suitable level for the receiver 54 to process.

A filter 84 (e.g., filter circuitry and/or software) may remove undesired noise from the received analog signals, such as cross-channel interference. The filter 84 may also remove one or more additional analog signals received by the antenna 55 that are at frequencies other than a desired signal. The filter 84 may include a combiner 85 to combine the received analog signals and/or remove frequencies other than those which are desired. In some embodiments, the combiner 85 may combine multiple received analog signals associated with different frequency bands (e.g., 2 frequency bands, 3 frequency bands, 4 frequency bands, and so on) to provide a combined analog signal associated with one frequency band. Moreover, the combiner 85 may include any suitable filter or filters to remove the undesired noise or signals from the received analog signals, such as a bandpass filter, a bandstop filter, a low pass filter, a high pass filter, and/or a decimation filter.

A demodulator 86 may remove a radio frequency envelope and/or extract a demodulated analog signal from the combined analog signal for processing. An analog-to-digital converter (ADC) 88 may receive the demodulated analog signal and convert the received signal to a digital signal of incoming data 90 to be further processed by the electronic device 10. Additionally, the receiver 54 may include any suitable additional components not shown, or may not include certain of the illustrated components, such that the receiver 54 may receive the received data 80 via the antenna 55. For example, the receiver 54 may include a mixer and/or a digital down converter.

Accordingly, the transmitter 52 and the receiver 54 may include the splitter 69 to split one or more analog signals and/or the combiner 85 to combine two or more analog signals. Moreover, the transmitter 52 and the receiver 54 may include the splitter 69 and/or the combiner 85 to filter one or more analog signals with frequencies outside one or more desired frequency ranges. In any case, the splitter 69 and/or the combiner 85 may include one or more inductors that may not scale with shrinking silicon components frequently relied on the transceiver 30. For example, an inductor of the splitter 69 and/or the combiner 85 may include a coil that may not scale with silicon components without losing effectiveness.

In some cases, the splitter 69 and/or the combiner 85 may also include one or more resistors each having a resistance. Moreover, the inductors of the splitter 69 and/or the combiner 85 may have an inductance including a resistive component (e.g., real part of impedance). Furthermore, a circuit area of an inductor may scale proportionally with a value of the resistive component of the inductance of the inductor. Accordingly, a surface area occupied by the splitter 69 and/or the combiner 85 may be reduced by combining one or more resistors and inductors of the splitter 69 and/or the combiner 85, as will be appreciated.

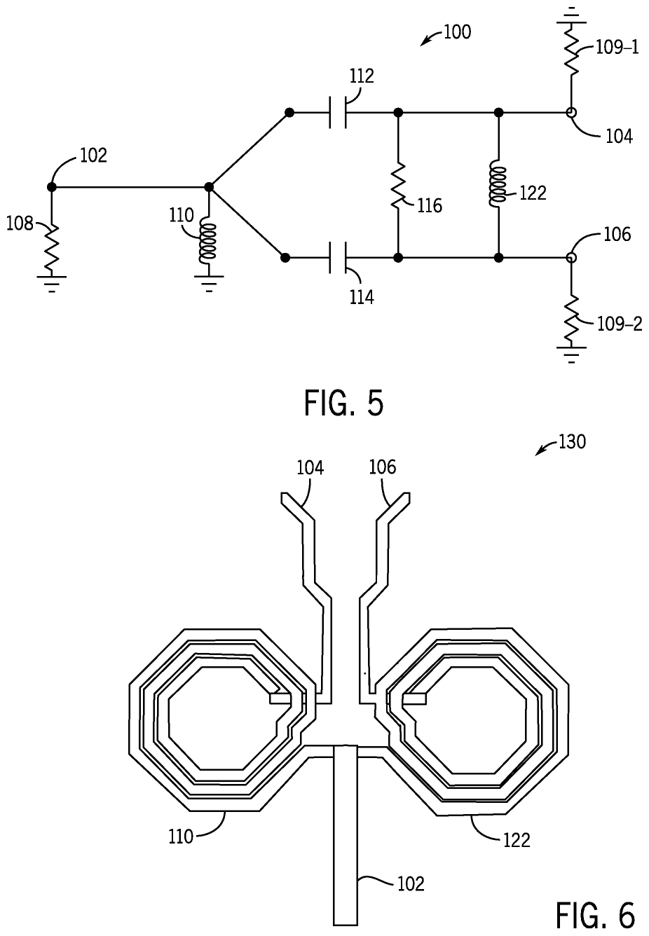

FIG. 5 is a circuit diagram of first splitter/combiner circuitry 100 disposed in the transceiver 30 of the electronic device of FIG. 1. The first splitter/combiner circuitry 100 may include an input node 102 (e.g., an input terminal), a first output node 104 (e.g., a first output terminal), and a second output node 106 (e.g., a second output terminal). The first splitter/combiner circuitry 100 may convey analog signals within a frequency range (e.g., less than 1 GHz frequency, 1-10 GHz frequency, 10-24 GHz frequency, 24-30 GHz frequency, and above 30 GHz frequency). When operating as the splitter 69, the first splitter/combiner circuitry 100 may split an analog signal (e.g., received from the power amplifier 66 of the transmitter 52) at the input node 102 into two signals at the first output node 104 and the second output node 106 (e.g., 1:2 splitter, one to two splitter).

Additionally or alternatively, the first splitter/combiner circuitry 100 may operate as the combiner 85. When operating as the combiner 85, the first output node 104 and the second output node 106 may function as inputs and the input node 102 may function as an output. For example, the first splitter/combiner circuitry 100 combines multiple analog signals received at the first output node 104 and the second output node 106 (e.g., received from the low noise amplifier 82 of the receiver 54) into a single signal at the input node 102 (e.g., 2:1 combiner circuitry, two to one combiner).

In the depicted circuit diagram, the input node 102 may be represented with an input resistor 108 having a first resistance Rₛ. Moreover, each of the first output node 104 and the second output node 106 may also be represented with output resistors 109-1 and 109-2. That is, the resistance of one or more components coupled to the input node 102, the first output node 104, and the second output node 106 may be represented by the first resistance Rₛ. In some cases, the first resistance Rₛ may include 500 ohms (Ω) or less, 200Ω or less, 100Ω or less, and so on, such as 50Ω. However, it should be appreciated that the described circuitry is by the way of example and in alternative or additional cases the components coupled to the input node 102, the first output node 104, and/or the second output node 106 may have a different resistance.

The input node 102 may be coupled to a first inductor 110 with a first inductance L₁ (e.g., an input inductance). In some cases, the first inductance L₁ of the first inductor 110 may include 2000 pico-Henry (pH) or less, 1000 pH or less, 300 pH or less, and so on (e.g., 300 pH based on receiving an analog signal with 27 GHz frequency). For example, the first inductance L₁ of the first inductor 110 may be determined by Equation 1 below:

$$\\ \begin{matrix}{L}_{1} = \frac{Rs}{{ω}_{o}} & ( Equation 1 )\end{matrix}$$

Moreover, the input node 102 and the first inductor 110 may be coupled to a first capacitor 112 and a second capacitor 114 on separate circuit branches. When operating as the splitter 69, the separate circuit branches may split an incoming signal from the power amplifier 66 received at the input node 102. When operating as the combiner 85, the separate circuit branches may combine an incoming signal from the low noise amplifier 82 received at the output nodes 104 and 106.

In some cases, the first capacitor 112 and the second capacitor 114 may have equal or substantially equal capacitance C₁. For example, the capacitance C₁ of the first capacitor 112 and the second capacitor 114 may include 500 femto-Farads (fF) or less, 400 fF or less, 300 fF or less, 200 fF or less, 100 fF or less, and so on (e.g., 117 fF based on receiving an analog signal with 27 GHz frequency).

The first capacitor 112 may be coupled to a resistor 116. For example, the resistor 116 may have a second resistance 2Rₛ that is based on (e.g., double) the first resistance Rₛ. The second capacitor 114 may be coupled to the resistor 116 via the second output node 106. For example, the second resistance 2Rₛ may include 1000Ω or less, 400Ω or less, 200Ω or less, and so on, such as 100Ω. Moreover, the first capacitor 112 may be coupled to a second inductor 122 with a second inductance L₂ via the first output node 104. Additionally, the second capacitor 114 may be coupled to the second inductor 122 via the second output node 106. As such, the second inductor 122 and the resistor 116 may be coupled in parallel to the nodes 104 and 106.

Accordingly, the second inductor 122 and the resistor 116 may have a first combined impedance. For example, the second inductor 122 and the resistor 116 may facilitate splitting an analog signal along with the first inductor 110, the first capacitor 112, and the second capacitor 114 when the first splitter/combiner circuitry 100 operates as the splitter 69. Moreover, the second inductor 122 and the resistor 116 may facilitate combining two analog signals along with the first inductor 110, the first capacitor 112, and the second capacitor 114 when the first splitter/combiner circuitry 100 operates as the combiner 85. In any case, in some cases, the second inductance L₂ of the second inductor 122 may include 2000 pico-Henry (pH) or less, 1000 pH or less, 300 pH or less, and so on (e.g., 600 pH based on receiving an analog signal with 27 GHz frequency). For example, the second inductance L₂ of the second inductor 122 may be determined by Equation 2 below:

$$\\ \begin{matrix}{L}_{2} = \frac{2 \cdot Rs}{{ω}_{o}} & ( Equation 2 )\end{matrix}$$

As shown in the Equation 2 above, the second inductance L₂ may include a resistive component 2Rₛ (e.g., based on (e.g., double) the first resistance Rₛ and/or based on (e.g., equal to) the second resistance 2Rₛ). Moreover, as mentioned above, a circuit area of an inductor may scale proportionally with a value of the resistive component of the inductance of the inductor. Accordingly, a circuit area of the second inductor 122 may scale proportionally with a value of the first resistance Rₛ and/or the second resistance 2Rₛ.

In any case, the first capacitor 112 may also be coupled to the first output node 104 represented by the output resistor 109-1 via the first input node 102. Additionally, the second capacitor 114 may be coupled to the second output node 106 represented by the output resistor 109-2 via the second output node 106. As mentioned above, the resistance of one or more components coupled to the first output node 104 and the second output node 106 may be represented by the first resistance Rₛ including 500Ω or less, 200Ω or less, 100Ω or less, and so on, such as 50Ω.

FIG. 6 is a first layout 130 of the first splitter/combiner circuitry 100. The first layout 130 depicts the first inductor 110 coupled to the input node 102. Moreover, the first layout 130 depicts the second inductor 122 coupled to the first output node 104 and the second output node 106. For simplicity, the first capacitor 112, the second capacitor 114, and the resistor 116 of the first splitter/combiner circuitry 100 are not shown in FIG. 6. In some cases, the first inductor 110, the second inductor 122, or both may occupy a circuit area equal to 10⁴ square micro meters (μm²) or less, 2500 μm² or less, 400 μm² or less, and so on (e.g., equal to or near 2025 μm² based on receiving an analog signal with 27 GHz frequency).

As mentioned above, the circuit area of the inductors may limit a reduction in the surface area occupied by the first splitter/combiner circuitry 100. Accordingly, reducing a circuit area of the second inductor 122 may facilitate reducing a surface area of the first splitter/combiner circuitry 100. As discussed above, the circuit area of the second inductor 122 may scale proportionally with a value of the first resistance Rₛ and/or the second resistance 2Rₛ. As shown in FIG. 5, in the first splitter/combiner circuitry 100, the second inductor 122 is coupled to the resistor 116 in parallel. Accordingly, combining the resistor 116 and the second inductor 122 of the splitter 69 and/or the combiner 85 (e.g., series coupling as compared to parallel coupling) may reduce a surface area occupied by the splitter 69 and/or the combiner 85.

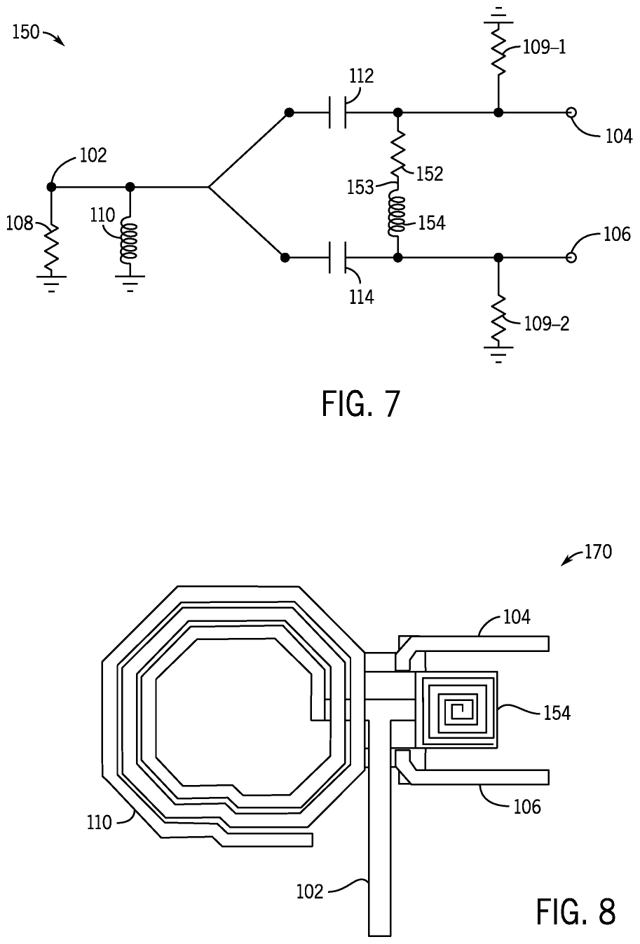

With the foregoing in mind, FIG. 7 is a circuit diagram of second splitter/combiner circuitry 150 with reduced surface area, as will be appreciated. Similar to the first splitter/combiner circuitry 100, the second splitter/combiner circuitry 150 may be disposed in the transceiver 30 of the electronic device of FIG. 1. Moreover, the second splitter/combiner circuitry 150 may operate as the splitter 69 and/or the combiner 85. Also, the second splitter/combiner circuitry 150 may convey analog signals within a frequency range (e.g., less than 1 GHz frequency, 1-10 GHz frequency, 10-24 GHz frequency, 24-30 GHz frequency, and above 30 GHz frequency). In some cases, the second splitter/combiner circuitry 150 and the first splitter/combiner circuitry 100 discussed above may convey analog signals within a similar frequency range.

The second splitter/combiner circuitry 150 may include the first inductor 110, the first capacitor 112, and the second capacitor 114 described above. Moreover, the second splitter/combiner circuitry 150 may include a resistor 152 coupled to the node 104 and a third inductor 154 coupled to the node 106. The resistor 152 and the third inductor 154 are coupled in series via a node 153. The resistor 152 and the third inductor 154 may have a second combined impedance equal to or substantially equal to the first combined impedance of the resistor 116 and the second inductor 122 of FIG. 5 discussed above.

With the foregoing in mind, a third inductance L₃ of the third inductor 154 may be reduced (e.g., reduced to half) compared to the second inductance L₂ of the second inductor 122 based on coupling in series to the resistor 152. In some cases, the third inductance L₃ of the third inductor 154 may include 2000 pico-Henry (pH) or less, 1000 pH or less, 300 pH or less, and so on (e.g., 300 pH based on receiving an analog signal with 27 GHz frequency). For example, the third inductance L₃ of the third inductor 154 may be determined by Equation 3 below:

$$\\ \begin{matrix}{L}_{3} = \frac{Rs}{{ω}_{o}} & ( Equation 3 )\end{matrix}$$

In the Equation 3 above, the third inductance L₃ may include a resistive component Rₛ. For example, the resistive component of the third inductance L₃ (e.g., Rₛ) of the third inductor 154 may be reduced (e.g., reduced to half) as compared to the resistive component of the second inductance L₂ (e.g., 2Rₛ) of the second inductor 122 described above. Moreover, as mentioned above, a circuit area of an inductor may scale proportionally with a value of the resistive component of the inductance of the inductor. As such, a circuit area of the third inductor 154 may occupy a reduced circuit area compared to the circuit area of the second inductor 122. Accordingly, the second splitter/combiner circuitry 150 may occupy a reduced surface area compared to the first splitter/combiner circuitry 100.

FIG. 8 is a second layout 170 of the second splitter/combiner circuitry 150. The second layout 170 depicts the first inductor 110 coupled to the input node 102. Moreover, the second layout 170 depicts the third inductor 154 coupled to the first output node 104 and the second output node 106. For simplicity, the first capacitor 112, the second capacitor 114, and the resistor 152 of the second splitter/combiner circuitry 150 are not shown. In the depicted embodiment, the third inductor 154 is square shaped. However, it should be appreciated that in other embodiments, the third inductor 154 may be implemented in a rectangular, triangular, octagonal, and circular, among other shapes, as will be appreciated.

In some cases, the first inductor 110 may occupy a circuit area equal to 10⁴ square micro meters (μm²) or less, 2500 μm² or less, 400 μm² or less, and so on (e.g., equal to or near 2025 μm² based on receiving an analog signal with 27 GHz frequency). Moreover, the third inductor 154 may occupy a circuit area equal to 10⁴ square micro meters (μm²) or less, 1250 μm² or less, 200 μm² or less, 100 μm² or less, 50 μm² or less, and so on (e.g., equal to or near 100 μm² based on receiving an analog signal with 27 GHz frequency).

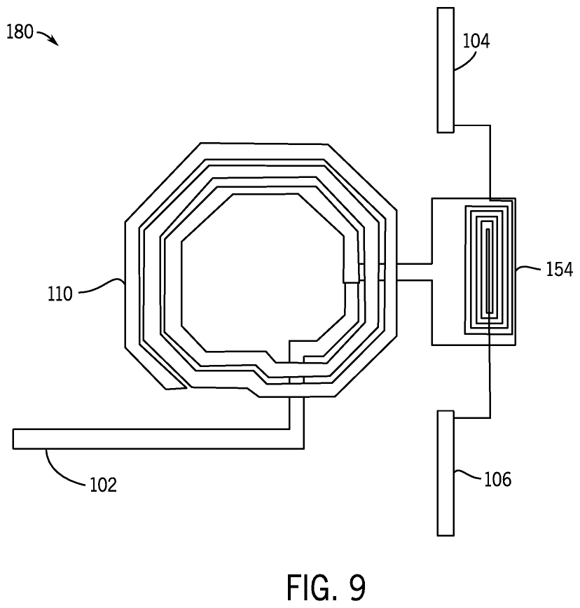

FIG. 9 is a third layout 180 of the second splitter/combiner circuitry 150. The third layout 180 depicts the first inductor 110 coupled to the input node 102. Moreover, the third layout 180 depicts the third inductor 154 coupled to the first output node 104 and the second output node 106. For simplicity, the first capacitor 112, the second capacitor 114, and the resistor 152 of the second splitter/combiner circuitry 150 are not shown. In the depicted embodiment, the third inductor 154 is rectangular shaped. However, as mentioned above, it should be appreciated that in other embodiments, the third inductor 154 may be implemented in other shapes.

In some cases, the first inductor 110 may occupy a circuit area equal to 10⁴ square micro meters (μm²) or less, 2500 μm² or less, 400 μm² or less, and so on (e.g., equal to or near 2025 μm² based on receiving an analog signal with 27 GHz frequency). Moreover, the third inductor 154 may occupy a circuit area equal to 50*100 micro meters (μm) or less, 25*100 micro meters (μm) or less, 25*50 μm or less, 10*20 μm or less, and so on (e.g., equal to or near 10*20 μm based on receiving an analog signal with 27 GHz frequency). Based at least in part on embodiments of FIGS. 8 and 9, the third inductor 154 may occupy a reduced circuit area compared to the circuit area of the second inductor 122. Accordingly, the second splitter/combiner circuitry 150 may occupy a reduced surface area compared to the first splitter/combiner circuitry 100.

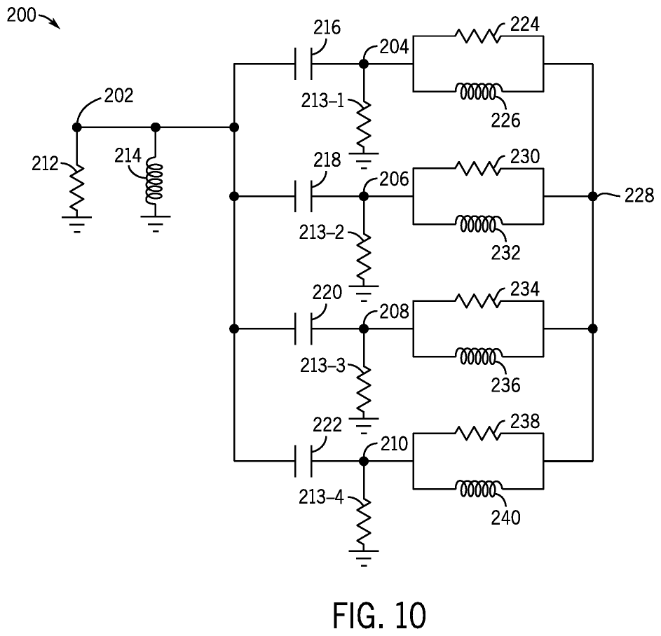

FIG. 10 is a circuit diagram of third splitter/combiner circuitry 200 disposed in the transceiver 30 of the electronic device of FIG. 1. The third splitter/combiner circuitry 200 may include an input node 202 (e.g., an input terminal), a first output node 204 (e.g., a first output terminal), a second output node 206 (e.g., a second output terminal), a third output node 208 (e.g., a third output terminal), and a fourth output node 210 (e.g., a fourth output terminal). The third splitter/combiner circuitry 200 may convey analog signals within a frequency range (e.g., less than 1 GHz frequency, 1-10 GHz frequency, 10-24 GHz frequency, 24-30 GHz frequency, and above 30 GHz frequency). When operating as the splitter 69, the third splitter/combiner circuitry 200 may split an analog signal (e.g., received from the power amplifier 66 of the transmitter 52) at the input node 202 into four signals at the first output node 204, the second output node 206, the third output node 208, and the fourth output node 210 (e.g., 1:4 splitter, one to four splitter).

Additionally or alternatively, the third splitter/combiner circuitry 200 may operate as the combiner 85. When operating as the combiner 85, the first output node 204, the second output node 206, the third output node 208, and the fourth output node 210 may function as inputs and the input node 202 may function as an output. For example, the third splitter/combiner circuitry 200 combines multiple analog signals received at the first output node 204, the second output node 206, the third output node 208, and the fourth output node 210 (e.g., received from the low noise amplifier 82 of the receiver 54) into a single signal at the input node 202 (e.g., 4:1 combiner circuitry, four to one combiner).

In the depicted circuit diagram, input circuitry coupled to the input node 202 may be represented with an input resistor 212 (e.g., an input resistance) having the first resistance Rₛ. Moreover, output circuitry coupled to the first output node 204, the second output node 206, the third output node 208, and the fourth output node 210 may each be represented with output resistors 213-1, 213-2, 213-3, and 213-4. That is, the resistance of one or more components coupled to the input node 202, the first output node 204, the second output node 206, the third output node 208, and the fourth output node 210 may be represented by the first resistance Rₛ.

In some cases, the input resistor 212 and the output resistors 213-1, 213-2, 213-3, and 213-4 of the third splitter/combiner circuitry 200 and the input resistor 108 and the output resistors 109-1 and 109-2 of the first splitter/combiner circuitry 100 and the second splitter/combiner circuitry 150 described above may have a nearly equal resistance (e.g., the first resistance Rₛ). For example, the first resistance Rₛ may include 500Ω or less, 200Ω or less, 100Ω or less, and so on, such as 50Ω. However, it should be appreciated that the described circuitry is by the way of example and in alternative or additional cases the components coupled to the input node 102, the first output node 204, the second output node 206, the third output node 208, and/or the fourth output node 210 may have a different resistance.

The input node 202 may be coupled to a first inductor 214 with a first inductance L₁₁ (e.g., an input inductance). In some cases, the first inductance L₁₁ of the first inductor 214 may include 2000 pico-Henry (pH) or less, 1000 pH or less, 300 pH or less, and so on (e.g., 300 pH based on receiving an analog signal with 27 GHz frequency). For example, the first inductance L₁₁ of the first inductor 214 may have a similar or different inductance compared to the first inductance L₁₁ of the first inductor 110 of FIGS. 5-9 described above. In some embodiments, the first inductance L₁₁ of the first inductor 214 may be determined by Equation 4 below:

$$\\ \begin{matrix}{L}_{11} = \frac{Rs}{\sqrt{3} \cdot {ω}_{o}} & ( Equation 4 )\end{matrix}$$

Moreover, the input node 202 and the first inductor 214 may be coupled to a first capacitor 216, a second capacitor 218, a third capacitor 220, and a fourth capacitor 222 on separate circuit branches. When operating as the splitter 69, the separate circuit branches may split an incoming signal from the power amplifier 66 received at the input node 202. When operating as the combiner 85, the separate circuit branches may combine an incoming signal from the low noise amplifier 82 received at the output nodes 204, 206, 208, and 210.

In some embodiments, the first capacitor 216, the second capacitor 218, the third capacitor 220, and the fourth capacitor 222 may have equal or substantially equal capacitance C₁₁. For example, the capacitance C₁₁ of the first capacitor 216, the second capacitor 218, the third capacitor 220, and the fourth capacitor 222 may include 500 fF or less, 400 fF or less, 300 fF or less, 200 fF or less, 100 fF or less, 50 fF or less, and so on.

The first capacitor 216 may be coupled to a first resistor 224 and a second inductor 226 via the first output node 204. In the depicted embodiment, the first resistor 224 and the second inductor 226 are coupled in parallel to the first output node 204 and a node 228. Moreover, the second capacitor 218 may be coupled to a second resistor 230 and a third inductor 232 via the second output node 206. The second resistor 230 and the third inductor 232 may be coupled in parallel to the second output node 206 and the node 228.

Similarly, the third capacitor 220 may be coupled to a third resistor 234 and a fourth inductor 236 via the third output node 208. The third resistor 234 and the fourth inductor 236 may be coupled in parallel to the third output node 208 and the node 228. Furthermore, the fourth capacitor 222 may be coupled to a fourth resistor 238 and a fifth inductor 240 via the fourth output node 210. The fourth resistor 238 and the fifth inductor 240 may be coupled in parallel to the fourth output node 210 and the node 228.

In some embodiments, the separate circuit branches may have similar impedances. For example, the first resistor 224, the second resistor 230, the third resistor 234, and the fourth resistor 238 may have the first resistance Rₛ. Moreover, the second inductor 226, the third inductor 232, the fourth inductor 236, and the fifth inductor 240 may have a second inductance L₂₂ that may be determined by Equation 5 below:

$$\\ \begin{matrix}{L}_{22} = \frac{\sqrt{3} \cdot Rs}{{ω}_{o}} & ( Equation 5 )\end{matrix}$$

As such, the second inductance L₂₂ and the first resistance Rₛ of each branch may have a third combined impedance. As shown in the Equation 5 above, the second inductance L₂₂ may include a resistive component (\sqrt{3}*Rₛ). In some cases, reducing an inductance of the second inductor 226, the third inductor 232, the fourth inductor 236, and the fifth inductor 240 may reduce a circuit area of the respective inductors, and therefore, a surface area of the third splitter/combiner circuitry 200. In specific cases, the resistive component of the second inductance L₂₂ (e.g., Rₛ) may be higher than the resistive component of the first inductance L₁₁ (e.g., (\sqrt{3}*Rₛ)) of the third splitter/combiner circuitry 200. For example, combining (e.g., coupling in series) the inductors 254, 258, 262, and 266 with respective parallel resistors 224, 230, 234, and 238 may cause a reduction in the second inductance L₂₂ of the inductors 226, 232, 236, and 240.

In any case, a circuit area of the inductors 226, 232, 236, and 240 of FIG. 10 may limit a reduction in the surface area occupied by the third splitter/combiner circuitry 200. Accordingly, reducing a circuit area of the inductors 226, 232, 236, and 240 may facilitate reducing a surface area of the third splitter/combiner circuitry 200. Moreover, the circuit area of the inductors 226, 232, 236, and 240 may scale proportionally with a value of the resistive component of the second inductance L₂₂. For example, combining the first resistor 224 and the second inductor 226 of the splitter 69 and/or the combiner 85 to provide the third combined impedance (e.g., series coupling as compared to parallel coupling) may reduce a surface area occupied by the splitter 69 and/or the combiner 85.

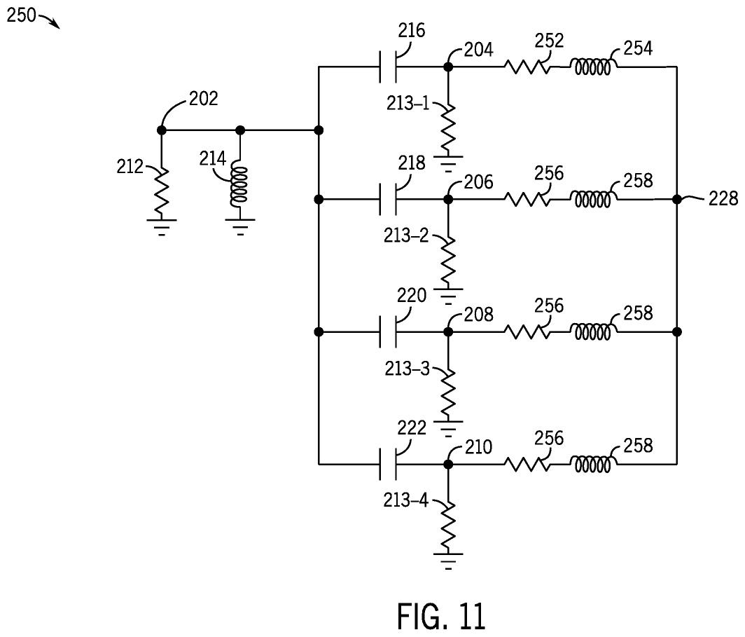

With the foregoing in mind, FIG. 11 is a circuit diagram of fourth splitter/combiner circuitry 250 with reduced surface area. Similar to the third splitter/combiner circuitry 200, the fourth splitter/combiner circuitry 250 may be disposed in the transceiver 30 of the electronic device of FIG. 1. Moreover, the fourth splitter/combiner circuitry 250 may operate as the splitter 69 and/or the combiner 85. Also, the fourth splitter/combiner circuitry 250 may convey analog signals within a frequency range (e.g., less than 1 GHz frequency, 1-10 GHz frequency, 10-24 GHz frequency, 24-30 GHz frequency, and above 30 GHz frequency). In some cases, the fourth splitter/combiner circuitry 250 and the third splitter/combiner circuitry 200 discussed above may convey analog signals within a similar frequency range.

The fourth splitter/combiner circuitry 250 may include the first inductor 214, the first capacitor 216, the second capacitor 218, the third capacitor 220, and the fourth capacitor 222 described above. Moreover, the fourth splitter/combiner circuitry 250 may include a fifth resistor 252 and a sixth inductor 254 coupled in series to the nodes 204 and 228 on a first branch. The fifth resistor 252 and the sixth inductor 254 may have a fourth combined impedance equal to or substantially equal to the third combined impedance of the first resistor 224 and the second inductor 226 coupled in parallel and discussed above with respect to FIG. 10.

Similarly, the fourth splitter/combiner circuitry 250 may include a sixth resistor 256 and a seventh inductor 258 coupled in series to the nodes 206 and 228 on a second branch, an seventh resistor 260 and an eighth inductor 262 coupled in series to the nodes 208 and 228 on a third branch, and an eighth resistor 264 and a ninth inductor 266 coupled in series to the nodes 210 and 228 on a fourth branch. The first branch, the second branch, the third branch, and the fourth branch may each have the fourth combined impedance equal to or substantially equal to the third combined impedance associated with the branches of the third splitter/combiner circuitry 200 of FIG. 10 discussed above.

With the foregoing in mind, a third inductance L₃₃ of the inductors 254, 258, 262, and 266 may be reduced compared to the second inductance L₂₂ of the inductors 226, 232, 236, and 240 of FIG. 10. For example, coupling the inductors 254, 258, 262, and 266 in series with the respective resistors 252, 256, 260, and 264 may reduce a resistive component of the third inductance L₃₃ for achieving the third combined impedance. In some cases, the third inductance L₃₃ of the inductors 254, 258, 262, and 266 may include 2000 pico-Henry (pH) or less, 1000 pH or less, 300 pH or less, and so on. For example, the third inductance L₃₃ of the inductors 254, 258, 262, and 266 may be determined by Equation 6 below:

$$\\ \begin{matrix}{L}_{33} = \frac{\sqrt{3} \cdot Rs}{4 \cdot {ω}_{o}} & ( Equation 6 )\end{matrix}$$

In the Equation 6 above, the third inductance L₃₃ may include a resistive component

$$\\ ( \frac{\sqrt{3} \cdot Rs}{4} ) .$$

For example, the resistive component of the third inductance L₃₃ of the inductors 254, 258, 262, and 266 may be reduced (e.g., reduced to a quarter) as compared to the resistive component of the second inductance L₂₂ (e.g., \sqrt{3}. Rs) of the inductors 226, 232, 236, and 240 of FIG. 10 described above. Moreover, as mentioned above, a circuit area of an inductor may scale proportionally with a value of the resistive component of the inductance of the inductor. As such, each of the inductors 254, 258, 262, and 266 may occupy a reduced circuit area compared to the circuit area of the inductors 226, 232, 236, and 240 described above. Accordingly, the fourth splitter/combiner circuitry 250 may occupy a reduced surface area compared to the third splitter/combiner circuitry 200.

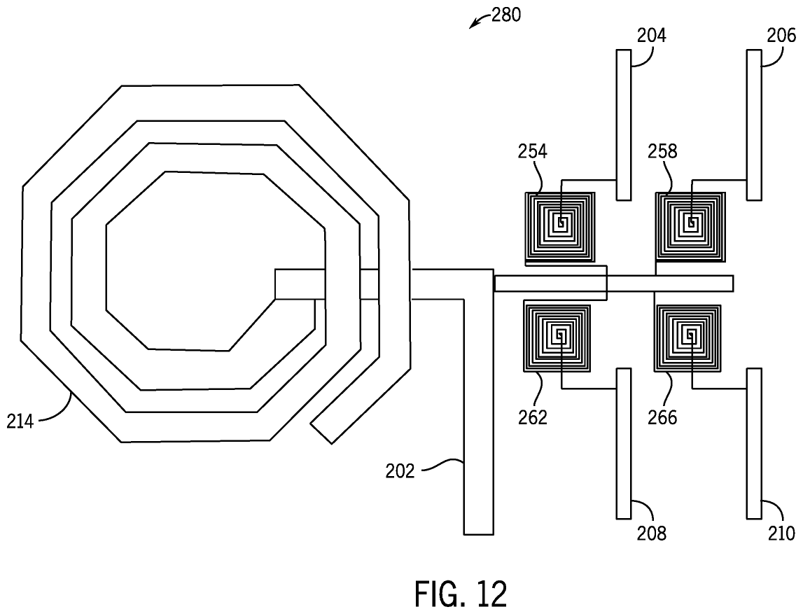

FIG. 12 is a fourth layout 280 illustrating an embodiment of the fourth splitter/combiner circuitry 250 with the reduced surface area. The fourth layout 280 depicts the first inductor 214 coupled to the input node 202. Moreover, the fourth layout 280 depicts the sixth inductor 254 coupled to the first output node 204, the seventh inductor 258 coupled to the second output node 206, the eighth inductor 262 coupled to the third output node 208, and the ninth inductor 266 coupled to the fourth output node 210. For simplicity, the first capacitor 216, the second capacitor 218, the third capacitor 220, the fourth capacitor 222, the fifth resistor 252, the sixth resistor 256, the seventh resistor 260, and the eighth resistor 264 of the fourth splitter/combiner circuitry 250 are not shown in FIG. 12. In some cases, one or more of the inductors 254, 258, 262, and 266 may occupy a circuit area equal to 50*50 micro meters (μm) or less, 25*25 micro meters (μm) or less, 15*15 μm or less, 10*10 μm or less, and so on (e.g., based on receiving an analog signal with 27 GHz frequency).

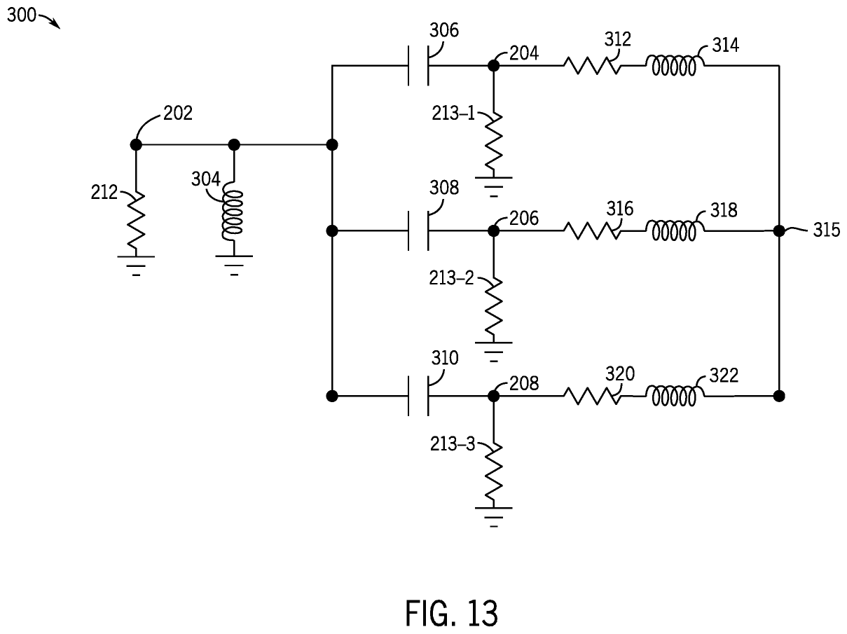

FIG. 13 depicts a fifth splitter/combiner circuitry 300 with reduced surface area. In some cases, the fifth splitter/combiner circuitry 300 may be implemented in place of the fourth splitter/combiner circuitry 250 and/or the third splitter/combiner circuitry 200. In the depicted embodiment, the fifth splitter/combiner circuitry 300 may include the input node 202 coupled to the input resistor 212. Moreover, the fifth splitter/combiner circuitry 300 may include the output resistors 213-1, 213-2, and 213-3 coupled to the respective nodes 204, 206, and 208. For example, the fifth splitter/combiner circuitry 300 may operate as a 1:3 splitter (e.g., the splitter 69) and/or a 3:1 combiner (e.g., the combiner 85).

The fifth splitter/combiner circuitry 300 may include a first inductor 304 coupled to the input node 202. Moreover, the fifth splitter/combiner circuitry 300 may include a first capacitor 306, a second capacitor 308, and a third capacitor 310. The fifth splitter/combiner circuitry 300 may also include a first resistor 312 and a second inductor 314 coupled in series to nodes 204 and 315 on a first branch. Similarly, the fifth splitter/combiner circuitry 300 may include a second resistor 316 and a third inductor 318 coupled in series to the nodes 206 and 315 on a second branch, and a third resistor 320 and a fourth inductor 322 coupled in series to the nodes 208 and 315 on a third branch. The first branch, the second branch, and the third branch may each have a similar combined impedance. In any case, similar to the embodiments described above, the second inductor 314, the third inductor 318, and the fourth inductor 322 may each occupy a reduced circuit area based on reduction of a resistive component of the respective inductances when coupled in series with the resistors 312, 316, and 320 respectively.

The fifth splitter/combiner circuitry 300 may have a fifth layout with a reduced surface area based on reducing a circuit area of the second inductor 314, the third inductor 318, and the fourth inductor 322. In some cases, one or more of the inductors 314, 318, and/or 322 may occupy a circuit area equal to 4000 square micro meters (μm²) or less, 1000 μm² or less, 200 ηm² or less, and so on.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ,” it is intended that such elements are to be interpreted under 35 U.S.C. 112(f). However, for any claims containing elements designated in any other manner, it is intended that such elements are not to be interpreted under 35 U.S.C. 112(f).

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

1. Splitter circuitry, comprising:
a first inductor, a first capacitor, and a second capacitor coupled at an input node,
a first resistor coupled to the first capacitor at a first output node,
a second inductor coupled to the first resistor and the first capacitor at the first output node,
a second resistor coupled to the second capacitor at a second output node, and
a third inductor coupled to the second resistor and the second capacitor at the second output node and coupled to the second inductor at a coupling node.

2. The splitter circuitry of claim 1, comprising
a third capacitor coupled to the first inductor, the first capacitor, and the second capacitor at the input node,
a third resistor coupled to the third capacitor at a third output node, and
a fourth inductor coupled to the third resistor and the third capacitor at the third output node and coupled to the second inductor and the third inductor at the coupling node.

3. The splitter circuitry of claim 2, comprising:
a fourth capacitor coupled to the first inductor, the first capacitor, the second capacitor, and the third capacitor at the input node,
a fourth resistor coupled to the fourth capacitor at a fourth output node, and
a fifth inductor coupled to the fourth resistor and the fourth capacitor at the fourth output node and coupled to the second inductor, the third inductor, and the fourth inductor at the coupling node.

4. The splitter circuitry of claim 2, wherein the splitter circuitry is configured to
receive an input analog signal via the input node, the input analog signal comprising
a first analog signal with a first frequency higher than a first threshold and higher than a second threshold,
a second analog signal with a second frequency higher than the first threshold and lower than the second threshold, and
a third analog signal with a third frequency lower than the first threshold and lower than the second threshold,
output the first analog signal via the first output node,
output the second analog signal via the second output node, and
output the third analog signal via the third output node.

5. The splitter circuitry of claim 2, wherein the splitter circuitry is configured to
receive a first analog signal via the first output node,
receive a second analog signal via the second output node,
receive a third analog signal via the third output node, and
output an output analog signal via the input node, the output analog signal comprising the first analog signal, the second analog signal, and the third analog signal.

6. The splitter circuitry of claim 1, wherein the first output node and the second output node are coupled to a low noise amplifier at the input node.

7. The splitter circuitry of claim 1, wherein
the first resistor, the first capacitor, and the second inductor are coupled to a first one or more antennas at the first output node, and
the second resistor, the second capacitor, and the third inductor are coupled to a second one or more antennas at the second output node.

8. The splitter circuitry of claim 1, wherein the first inductor occupies a first area, the second inductor, and the third inductor each occupying a respective area equal to or less than a quarter of the first area.

9. An electronic device, comprising:
a plurality of antennas configured to transmit one or more signals; and
splitter circuitry coupled to the plurality of antennas, the splitter circuitry comprising
a first inductor, a first capacitor, and a second capacitor coupled at an input node,
a first resistor coupled to the first capacitor at a first output node, a first one or more antennas of the plurality of antennas being coupled to the first resistor and the first capacitor at the first output node,
a second inductor coupled to the first resistor, the first capacitor, and the first one or more antennas at the first output node,
a second resistor coupled to the second capacitor at a second output node, a second one or more antennas of the plurality of antennas being coupled to the second resistor and the second capacitor at the second output node, and
a third inductor coupled to the second resistor, the second capacitor, and the second one or more antennas at the second output node.

10. The electronic device of claim 9, comprising
a third capacitor coupled to the first inductor, the first capacitor, and the second capacitor at the input node,
a third resistor coupled to the third capacitor at a third output node, a third one or more antennas of the plurality of antennas being coupled to the third resistor and the third capacitor at the third output node, and
a fourth inductor coupled to the third resistor, the third capacitor, and the third one or more antennas at the third output node.

11. The electronic device of claim 10, comprising a power amplifier coupled to the first inductor, the first capacitor, the second capacitor, and the third capacitor at the input node, the power amplifier configured to provide a first signal, a second signal, and a third signal to the splitter circuitry, wherein the splitter circuitry is configured to
receive the first signal with a first frequency equal to or higher than a first threshold and equal to or higher than a second threshold via the input node,
receive the second signal with a second frequency equal to or higher than the first threshold and lower than the second threshold via the input node,
receive the third signal with a third frequency lower than the first threshold and lower than the second threshold via the input node,
provide the first signal via the first output node,
provide the second signal via the second output node, and
provide the third signal via the third output node.

12. The electronic device of claim 10, wherein the splitter circuitry comprises
a fourth capacitor coupled to the first inductor, the first capacitor, the second capacitor, and the third capacitor at the input node,
a fourth resistor coupled to the fourth capacitor at a fourth output node, a fourth one or more antennas of the plurality of antennas being coupled to the fourth resistor and the fourth capacitor at the fourth output node, and
a fifth inductor coupled to the fourth resistor, the fourth capacitor, and the fourth one or more antennas at the fourth output node.

13. The electronic device of claim 10, wherein the splitter circuitry is configured to
receive a first input signal via the first output node,
receive a second input signal via the second output node,
receive a third input signal via the third output node, and
provide a combined output signal comprising the first input signal, the second input signal, and the third input signal via the input node.

14. The electronic device of claim 9, wherein an inductance value of the second inductor and the third inductor are a quarter of or less than a quarter of an inductance value of the first inductor.

15. A radio frequency (RF) receiver, comprising:
a low noise amplifier; and
combiner circuitry coupled to the low noise amplifier, the combiner circuitry comprising
a first inductor, a first capacitor, and a second capacitor coupled at an output node,
a first resistor coupled to the first capacitor at a first input node, the low noise amplifier being coupled to the first resistor and the first capacitor at the first input node,
a second inductor coupled to the first capacitor and the first resistor at the first input node,
a second resistor coupled to the second capacitor at a second input node, the low noise amplifier being coupled to the second resistor and the second capacitor at the second input node, and
a third inductor coupled to the second capacitor and the second resistor at the second input node.

16. The RF receiver of claim 15, comprising
a third capacitor coupled to the first inductor, the first capacitor and the second capacitor at the output node,
a third resistor coupled to the third capacitor at a third input node, the low noise amplifier being coupled to the third resistor and the third capacitor at the third input node, and
a fourth inductor coupled to the third capacitor and the third resistor at the third input node.

17. The RF receiver of claim 16, comprising
a fourth capacitor coupled to the first inductor, the first capacitor, the second capacitor, and the third capacitor at the output node,
a fourth resistor coupled to the fourth capacitor at a fourth input node, and
a fifth inductor coupled to the fourth resistor and the fourth capacitor at the fourth input node.

18. The RF receiver of claim 16, wherein the combiner circuitry is configured to
receive a first input signal via the first input node,
receive a second input signal via the second input node,
receive a third input signal via the third input node,
provide a combined output signal comprising the first input signal, the second input signal, and the third input signal via the output node.

19. The RF receiver of claim 18, wherein the low noise amplifier is configured to provide the first input signal to the first input node, the second input signal to the second input node, and the third input signal to the third input node.

20. The RF receiver of claim 15, wherein the combiner circuitry is configured to receive a first input signal via the output node, provide a first output signal via the first input node, and provide a second output signal via the second input node.
